(19) United States
(12) Patent Application Publication
(10) Pub. No.: US 2004/0257125 A1
(43) Pub. Date: Dec. 23, 2004

(54) Trickle current-cascode DAC

(76) Inventors: William W. Cheng, Redondo Beach, CA (US); Don C. Devendorf, Carlsbad, CA (US); Erick M. Hirata, Torrance, CA (US); Roger N. Kosaka, Torrance, CA (US); Christopher B. Langit, Gardena, CA (US); Lloyd F. Linder, Agoura Hills, CA (US)

Correspondence Address: David T. Yang, Esq., Morrison & Foerster LLP, Suite 3500, 555 est Fifth Street, Los Angeles, CA, 90013-1024, US

(21) Appl. No.: 10/698,257

(22) Filed: Oct. 30, 2003

Related U.S. Application Data
(63) Continuation of application No. 60/480,987, filed on Jun. 23, 2003.

(51) Int. Cl. H03B 1/00

(52) U.S. Cl. 327/108

(57) ABSTRACT

A current switch. The novel current switch includes a differential pair of transistors Q1 and Q2, a pair of cascode transistors Q_{A} and Q_{B} coupled to Q1 and Q2, respectively, and a circuit for maintaining Q_{A} and Q_{B} in an ‘on’ state regardless of the states of Q1 and Q2. The circuit for keeping Q_{A} and Q_{B} on includes first and second current sources adapted to supply first and second trickle currents to the emitters of Q_{A} and Q_{B}, respectively. The bases of Q_{A} and Q_{B} are connected in common to a voltage source V_{REF4}, which, in an illustrative embodiment, is implemented using a Schottky diode for lower impedance. The circuit for driving Q1 and Q2 may also be implemented using a current switch with trickle current, cascode transistors Q14 and Q15 to further improve settling times.

### CROSS-REFERENCE TO RELATED APPLICATIONS

This application claims the benefit of U.S. Provisional Application No. 60/480,987, filed Jun. 20, 2003, the disclosure of which is hereby incorporated by reference.

### BACKGROUND OF THE INVENTION

1. Field of the Invention:

The present invention relates to electrical and electronic circuits and systems. More specifically, the present invention relates to digital to analog converters.

2. Description of the Related Art:

Digital to analog converters are widely used for converting digital signals to analog signals for many electronic circuits. For example, a high resolution, high speed digital to analog converter (DAC) may find application in video circuits, high quality audio, instrumentation applications, and in the transmit path for high dynamic range communications applications. It may also be used in high speed analog to digital converters (ADCs) that utilize DACs such as successive approximation ADCs or subranging ADCs. There is currently a desire for faster DAC operating speed and improved accuracy relative to conventional designs.

A common DAC, the current summing DAC, generates an analog output signal by selectively switching a number of current sources (or cells) into or out of a current summing device in response to a digital input signal. Each DAC cell includes a current source and a current steering switch, which is typically implemented using a differential pair of transistors. As the input to a particular cell is changed, the transistors might be commanded to go from on to off, or from off to on. There is a finite delay time while the transistors are changing state. This delay time is largely a function of the transistor's collector to base capacitance C_{CB}, the impedance of the driving source, and the value of the load resistance. Even though the transistors are being used as current steering transistors, they have finite gain. Therefore, the Miller effect is applied to C_{CB}, increasing the parasitic capacitance. This slows the response time of the switches, reducing the overall operating speed of the DAC.

Additionally, as the voltages on the collectors of the steering transistors vary, they are coupled (albeit considerably attenuated) to the collectors of the current sources. These attenuated voltages will impact the accuracy of the current sources. All of these perturbations must also settle to within the accuracy of the DAC. The two areas discussed above limit the speed at which the DAC can be run and the DAC's ability to meet its accuracy requirements.

Furthermore, the inputs to the DAC cells are typically driven by standard ECL (emitter-coupled logic) circuits. These circuits also have a switching delay, as well as an output voltage swing defined as being from about −0.9 V to −1.7 V. This voltage swing is larger than desired. The larger the voltage swing, the more undesirable energy is coupled into the DAC circuitry and the longer it takes to settle to the correct value.

Hence, there is a need in the art for an improved digital to analog converter having a faster operating speed and improved accuracy over prior approaches.

### SUMMARY OF THE INVENTION

The need in the art is addressed by the current switch of the present invention. The novel current switch includes a differential pair of transistors Q1 and Q2, a pair of cascode transistors Q_{A} and Q_{B} coupled to Q1 and Q2, respectively, and a circuit for maintaining Q_{A} and Q_{B} in an ‘on’ state regardless of the states of Q1 and Q2. The circuit for keeping Q_{A} and Q_{B} on includes first and second current sources adapted to supply first and second trickle currents to the emitters of Q_{A} and Q_{B}, respectively. The bases of Q_{A} and Q_{B} are connected in common to a voltage source V_{REF4}, which, in an illustrative embodiment, is implemented using a Schottky diode for lower impedance. The circuit for driving Q1 and Q2 may also be implemented using a current switch with trickle current, cascode transistors Q14 and Q15 to further improve settling times.

### BRIEF DESCRIPTION OF THE DRAWINGS

FIG. 1 is a schematic of a common conventional implementation of an integrated circuit DAC.

FIG. 2 is a simplified schematic of a conventional DAC cell switch driver.

FIG. 3 is a simplified schematic of a DAC designed in accordance with an illustrative embodiment of the teachings of the present invention.

FIG. 4 is a simplified schematic of a conventional implementation of a voltage source for supplying V_{REF4}.

FIG. 5 is a simplified schematic of a voltage source for supplying V_{REF4} to the cascode circuit, in accordance with an illustrative embodiment of the teachings of the present invention.

FIG. 6 is a simplified schematic of a DAC cell switch driver designed in accordance with an illustrative embodiment of the teachings of the present invention.

### DESCRIPTION OF THE INVENTION

Illustrative embodiments and exemplary applications will now be described with reference to the accompanying drawings to disclose the advantageous teachings of the present invention.

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

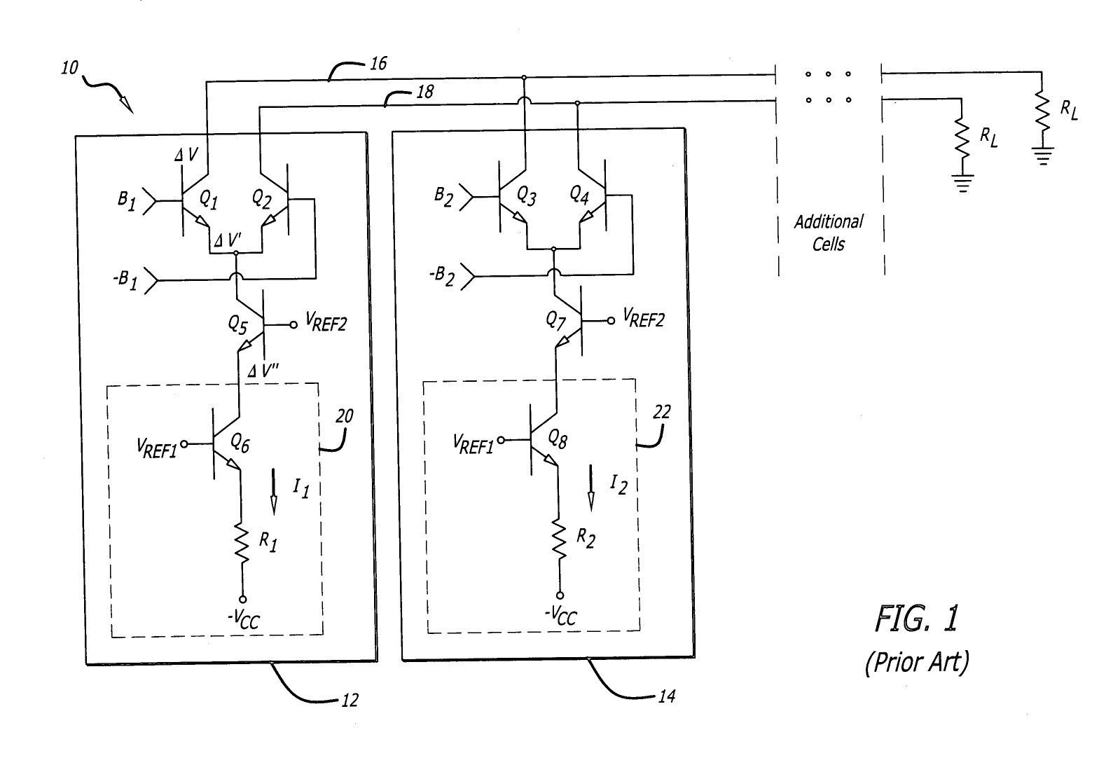

FIG. 1 is a simplified schematic of a common conventional implementation of an integrated circuit DAC 10. Two of N current steering cells 12 and 14 are shown in the figure. In practice there will be several more cells. The number of cells N depends on the desired resolution of the DAC. Each cell 12, 14 selectively switches current between a first current summing bus 16 and a second current summing bus 18 in response to an N-bit digital input signal. For example, the first cell 12 is controlled by a signal B₁, representing the least significant bit (LSB) of the N-bit digital word, and the next cell 14 is controlled by a signal B₂, representing the next LSB. Each current summing bus 16, 18 is connected to ground through a load resistance R_{L}. The analog output of the DAC 10 is taken from the voltage difference between the two buses 16 and 18.

Each DAC cell 12 and 14 is thus a current switch, which is typically implemented using a differential pair of transistors (Q1, Q2 in the first cell 12, and Q3, Q4 in the second cell 14). The current to be steered is set by a current source 20 and 22, respectively. These two current sources 20 and 22 are buffered from the switching transistors Q1, Q2 and Q3, Q4 by two cascode transistors Q5 and Q7, respectively. As shown in FIG. 1, the collector of Q1 is connected to the first bus 16, the base of Q1 is connected to B₁, and the emitter of Q1 is connected in common with the emitter of Q2 to the collector of Q5. The collector of Q2 is connected to the second bus 18, and the base of Q2 is connected to −B₁. Similarly, for the second cell 14, the collector of Q3 is connected to the first bus 16, the base of Q3 is connected to B₂, and the emitter of Q3 is connected in common with the emitter of Q4 to the collector of Q7. The collector of Q4 is connected to the second bus 18, and the base of Q4 is connected to −B₂. The bases of Q5 and Q7 are connected to a reference voltage V_{REF2}.

The current source 20 is implemented using a transistor Q6 having a base connected to a reference voltage V_{REF1}, a collector connected to the emitter of Q5, and an emitter connected to a voltage supply −V_{CC} through a resistor R1. The current 11 supplied by the current source 20 is given approximately by I₁=(V_{REF1}−0.8+V_{CC})/R1. Similarly, the current source 22 is implemented using a transistor Q8 having a base connected to V_{REF1}, a collector connected to the emitter of Q7, and an emitter connected to −V_{CC} through a resistor R2. The current I₂ supplied by the current source 22 is given approximately by I₂=(V_{REF1}−0.8+V_{CC})/R2.

The function of the transistors Q1 and Q2 is to steer the current I₁ out of either the first bus 16 or the second bus 18 depending on the digital code input to the pair. For example, if B₁ is more positive than −B₁, then Q1 is turned on and Q2 off. Thus, current is steered through Q1, drawing current from the first bus 16 but not from the second bus 18. If B₁ is more negative than −B₁, then Q1 is turned off and Q2 on, resulting in current being drawn through Q2 from the second bus 18 but not the first bus 16. The second pair of transistors, Q3 and Q4, function the same way in response to the code B₂. In order to increase the operating speed of the DAC 10, the switching time of the transistors (Q1, Q2, Q3, Q4) needs to be reduced. One reason the switches have a slow settling time is because they are each tied to a current summing bus having a finite impedance R_{L}, causing the transistors to have gain. Since they have gain, they have parasitic capacitances C_{CB} located between the base and collector, and these capacitances are multiplied by the gain (Miller effect). This slows down the circuit.

Secondly, as the voltages on the current summing buses 16 and 18 change (i.e., the voltages ΔV on the collectors of the steering transistors), those voltages are coupled (albeit considerably attenuated) through the capacitances of the switching transistors to the collectors of the current source cascode transistors Q5 and Q7 where they are further attenuated. These attenuated voltages (ΔV′) will impact the current sources Q6 and Q8, since their collector voltages (ΔV″) are thus changing as a function of the voltages on the current buses 16 and 18. All of the perturbations must also settle to within the accuracy of the DAC. The two areas discussed above combine to, in part, establish the speed in which the DAC can be run and the DAC's ability to meet its accuracy requirements.

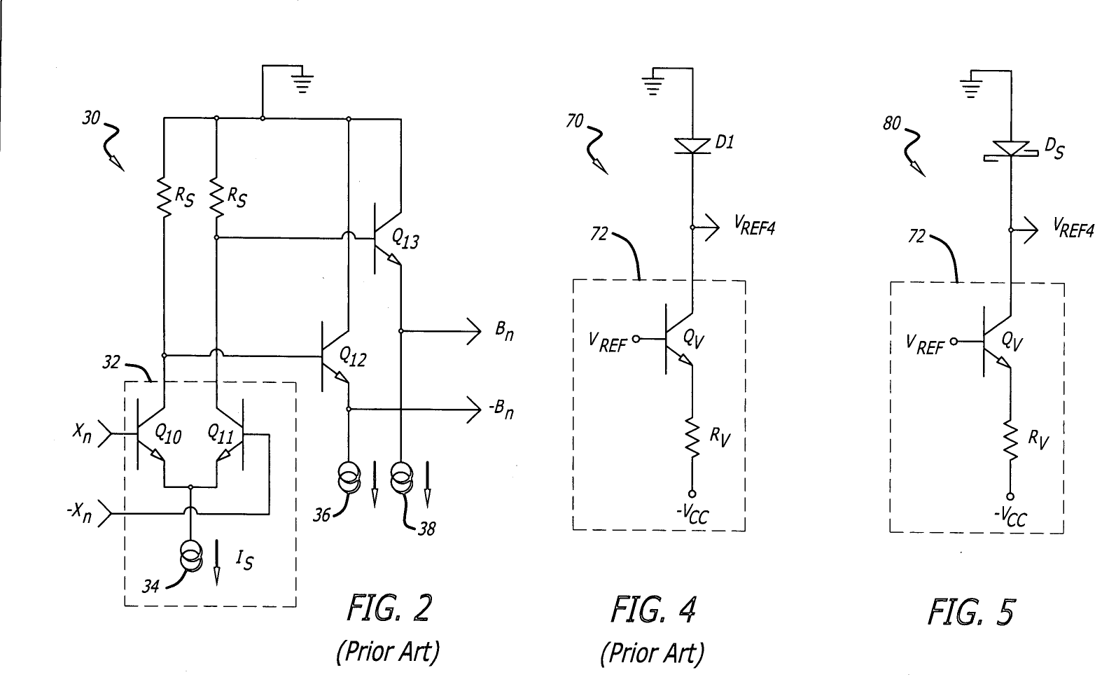

The current steering transistors Q1, Q2 and Q3, Q4 of the DAC 10 shown in FIG. 1 are typically driven by a standard ECL circuit as shown in FIG. 2. FIG. 2 is a simplified schematic of a conventional DAC cell switch driver 30. The circuit 30 includes a current switch 32 comprised of a differential pair of transistors Q10 and Q11, having emitters connected in common to a current source 34 generating a current I_{S}. The bases of Q10 and Q11 are connected to digital input signals Xₙ and −Xₙ, respectively, and the collectors are each coupled to ground through a resistor R_{S}. The collectors of Q10 and Q11 are connected to the bases of emitter follower transistors Q12 and Q13, respectively. The collectors of Q12 and Q13 are connected to ground, and their emitters are each connected to a current source 36 and 38, respectively. The output voltage Bₙ is taken at the emitter of Q13, and the output voltage −Bₙ is taken at the emitter of Q12.

This circuit 30 has a similar problem as the DAC cells 12, 14 of FIG. 1: the current switch 32 has a defined switching delay. In addition, the lower the output impedance of the driver circuit 30, the better the combined circuits 10 and 30 perform. The output impedance of the circuit 30, however, is proportional to the resistance R_{S}, and there are limits on how small R_{S} can be. The output voltage swing is defined as being from −0.9 V to less than −1.7 V. This swing places a minimum value on R_{S} for a reasonable current level I_{S} since the minimum output voltage is less than or equal to −1.7 volts. Therefore, I_{S}R_{S}+0.9 V must be greater than 1.7 V. For an I_{S} of 0.5 mA, R_{S} must therefore be greater than 1.6 kΩ.

Furthermore, this drive circuit 30 results in a drive voltage that goes from −0.9 V to −1.7 V for a voltage swing of 0.8 V or greater. This voltage swing is larger than desired. The larger the voltage swing the more undesirable energy is coupled into the DAC circuitry and the longer it takes to settle to the correct value.

The present invention improves upon the prior art by introducing a novel current switch having a cascode circuit with idle or ‘trickle’ currents placed at the outputs of the switching transistors. These cascode circuits decrease the time required by the switching transistors to switch on and off, thereby decreasing settling time. Used in a DAC cell, the cascode circuit also isolates the switching transistors from the output summing nodes, thereby improving the DAC's overall accuracy and dynamic range. Used in a driver circuit, it also allows for the reduction of the output voltage swing without increasing the output impedance, thereby improving the overall DAC's settling time.

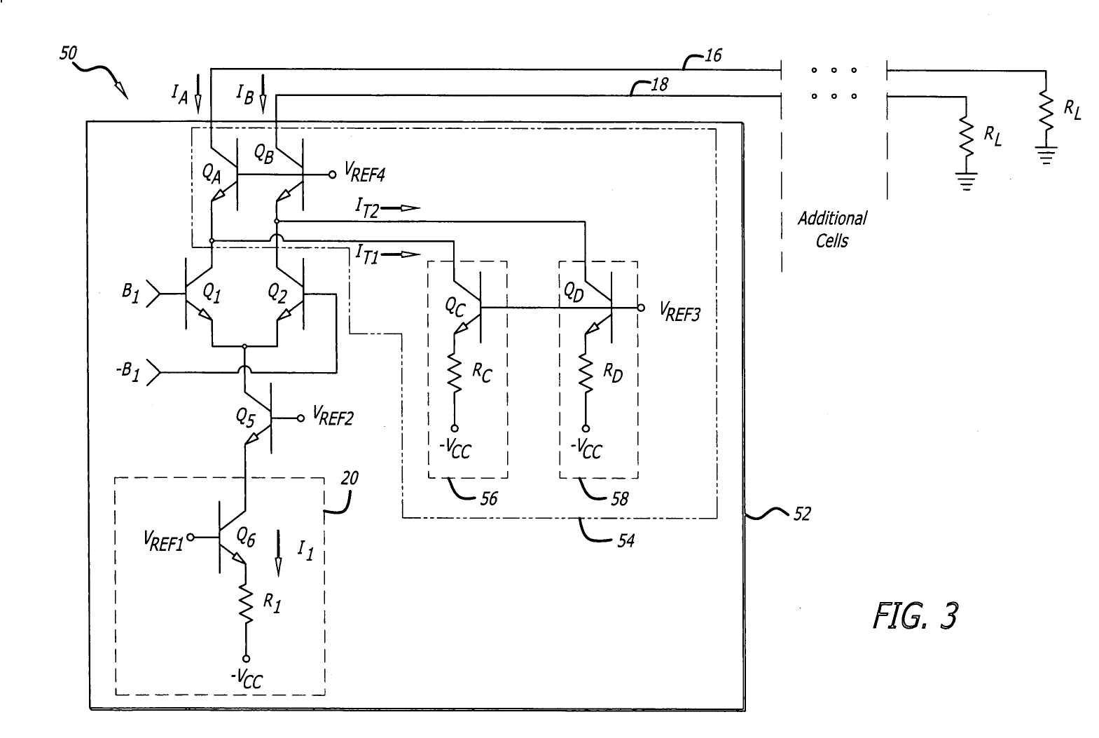

FIG. 3 is a simplified schematic of a DAC 50 designed in accordance with an illustrative embodiment of the teachings of the present invention. The DAC 50 includes a novel current switch or DAC cell 52 (only one cell of many is shown in the figure for simplicity). The current switch 52 includes a differential pair of transistors Q1 and Q2, whose bases are connected to complementary input signals B₁ and −B₁, respectively, and a current source 20 that supplies a current I₁. The current source 20 may be buffered from the switching transistors Q1, Q2 by a cascode transistor Q5, having a base connected to a reference voltage V_{REF2} and a collector connected to the common emitters of Q1 and Q2. In the illustrative embodiment, the current source 20 is implemented using a transistor Q6 having a base connected to a reference voltage V_{REF1}, a collector connected to the emitter of Q5, and an emitter connected to a voltage supply −V_{CC} through a resistor R1.

In accordance with the teachings of the present invention, the current switch 52 also includes a cascode circuit 54. The cascode circuit 54 includes a pair of cascode transistors Q_{A} and Q_{B} coupled to the collectors of the switching transistors Q1 and Q2, respectively. The bases of Q_{A} and Q_{B} are connected in common to a reference voltage VREF4, and the outputs of the currents switch 52 are now taken at the collectors of QA and QB. The collector of Q_{A} is therefore coupled to the first current summing bus 16, drawing a current I_{A}, and the collector of Q_{B} is coupled to the second current summing bus 18, drawing a current I_{B}. There is one important addition to the circuit 54 and that is the addition of the trickle current sources 56 and 58 coupled to the emitters of Q_{A} and Q_{B}, respectively.

In the illustrative embodiment, the current source 56 is implemented using a transistor Q_{C} having a base connected to a reference voltage V_{REF3}, an emitter connected to −V_{CC} through a resistor R_{C}, and a collector connected to the emitter of Q_{A}, drawing a current I_{T1}. The current source 58 is implemented using a transistor Q_{D} having a base connected to V_{REF3}, an emitter connected to −V_{CC} through a resistor R_{D}, and a collector connected to the emitter of Q_{B}, drawing a current I_{T2}.

Because of the addition of the trickle circuits 56 and 58, the cascode transistors Q_{A} and Q_{B} are always on. The trickle currents I_{T1} and I_{T2} hold the transistors Q_{A} and Q_{B} in the linear range of operation, even when a particular switching transistor Q1 or Q2 is turned off. This is most critical to the delay time performance of the circuit. As an example of how the circuit performs, assume −B₁ is more positive than B₁. This condition turns ‘on’ transistor Q2 and allows 11 to be drawn from the second current bus 18. Q1 is off and no portion of 11 passes through from the first bus 16. It must be noted that both trickle currents I_{T1} and I_{T2} continue to be drawn through Q_{A} and Q_{B}, respectively. In this case I_{A}=I_{T1} and I_{B}=I₁+I_{T2}.

It is easily shown that the trickle currents will not impact the current summing accuracy of the DAC 50. Let the output voltage V_{OUT}=V_{A}−V_{B}. Looking at the contribution of I_{T1} and I_{T2}, V_{OUT}=I_{T1} R_{L}−I_{T2} R_{L}−I₁R_{L}, or V_{OUT}=R_{L}[(I_{T1}−I_{T2})−I₁]. If I_{T1}=I_{T2}, then the output would be V_{OUT}=−R_{L} I₁, the correct value. Even if I_{T1} and I_{T2} are not perfectly matched, their contribution to the output V_{OUT} is simply an offset (since it does not vary with the input code) and can be easily removed through trimming. This is accomplished when the differential offset is trimmed to zero for all the cells. The trickle currents are about 10 to 100 times smaller than I₁ and are chosen for optimum DAC performance.

By adding the cascode circuit 54 to the current switch 52, the turn on delay time for the switching transistors Q1, Q2 is significantly improved. In the prior art, the turn on time was dominated by C_{CB}, the Miller effect, and the node impedance R_{L}. Now, with the improved implementation, since the transistors Q_{A} and Q_{B} are always on, the collectors of Q1 and Q2 are held at a constant voltage which is approximately V_{REF4}−0.8 V. This effectively eliminates the Miller effect. Also since the collectors of Q1 and Q2 are connected to the emitters of Q_{A} and Q_{B}, they no longer work into the impedance of the summing node of R_{L}. Instead, there is a much lower impedance since Q_{A} and Q_{B} are grounded base amplifiers. Between the elimination of the Miller effect and the lowering of the impedance seen by the collectors of Q1 and Q2, the turn on/turn off times of Q1 and Q2 are significantly reduced, thereby increasing the speed of operation of the DAC 50.

The second area of performance improvement involves how voltage variations on the buses 16 and 18 reflect down to the collector of the current source 20. While the magnitude of the current source 20 collector voltage is difficult to calculate exactly, it is easy to see that the cascode stages act as an additional buffer or attenuator between the buses 16 and 18 and the current source 20. This essentially eliminates bus voltage variations as a cause of current source errors.

The following table gives sample values for the components of FIG. 3:

| | | |
|---|---|---|
| -V_{cc} | −5 | V |
| V_{REF1} | −2.7 | V |
| V_{REF2} | −1.8 | V |
| V_{REF3} | −3.95 | V |
| V_{REF4} | −0.8 | V |
| R₁ | 2.4 | kΩ |
| R_{C} | 5 | kΩ |
| R_{D} | 5 | kΩ |
| R_{L} | 50 | Ω (for a 9-bit unary, or 14-bit binary DAC) |
| I₁ | 0.624 | mA |

It should be pointed out that the lower the impedance of the voltage source V_{REF4}, the more effective Q_{A} and Q_{B} become in providing the benefits described. As the V_{REF4} impedance goes to zero, any transient perturbations at the load resistance is shunted to virtual ground. This helps to isolate these dynamic settling errors from the switch pair Q1, Q2. Under normal circumstances, V_{REF4} would be implemented as shown in FIG. 4.

FIG. 4 is a simplified schematic of a conventional implementation of a voltage source 70 for supplying V_{REF4}. The voltage source 70 includes a diode D1 having an anode connected to ground and a cathode connected to a current source 72. The current source 72 is implemented using a transistor Q_{V} having a base connected to a reference voltage V_{REF}, an emitter connected to −V_{CC} through a resistor R_{V}, and a collector connected to the cathode of D1. The output voltage V_{REF4} is taken at the cathode of D1. Normally, D1 would simply be another transistor connected as a diode. In accordance with the teachings of this invention, however, the diode is implemented as a Schottky diode, as shown in FIG. 5.

FIG. 5 is a simplified schematic of a voltage source 80 for supplying V_{REF4} to the cascode circuit 54, in accordance with an illustrative embodiment of the teachings of the present invention. The circuit 80 is identical to that of FIG. 4, except the diode D1 is replaced with a Schottky diode Ds. A Schottky diode has a lower on resistance, a higher transition frequency ft, and a low impedance over a wider bandwidth than the normal diode-connected transistor. When used as the reference voltage source V_{REF4} for the cascode transistors Q_{A} and Q_{B}, its low impedance improves the cascode transistor stage's isolation and settling time.

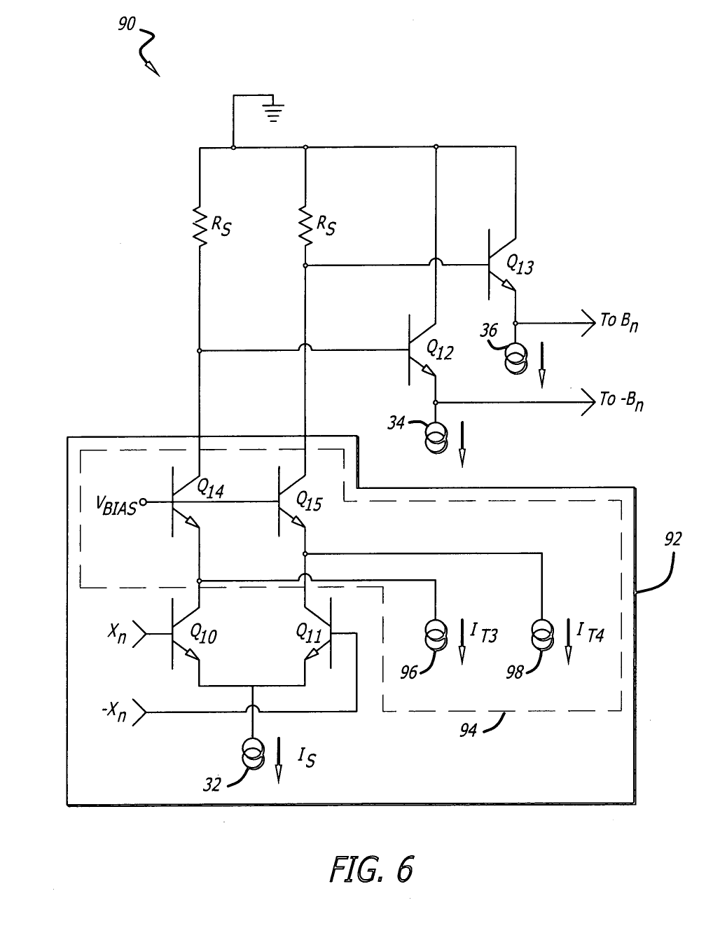

The trickle current, cascode circuit 54 can be used in a similar manner to improve the speed of the current switch of the DAC cell switch driver. FIG. 6 is a simplified schematic of a DAC cell switch driver 90 designed in accordance with an illustrative embodiment of the teachings of the present invention. The driver 90 is similar to that of FIG. 2, except the current switch 32 is replaced with a novel current switch 92, having a trickle current, cascode circuit 94. The current switch 92 includes a differential pair of transistors Q10 and Q11, having bases connected to complementary input signals Xₙ and −Xₙ, respectively, emitters connected in common to a current source 32 that supplies a current I_{S}, and collectors connected to the cascode circuit 94.

The cascode circuit 94 includes a pair of cascode transistors Q14 and Q15 coupled to the collectors of the switching transistors Q10 and Q11, respectively. The bases of Q14 and Q15 are connected in common to a voltage supply V_{BIAS}, the collectors of Q14 and Q15 are each connected to ground through a resistor R_{S}, and the emitters are each connected to a current source 96 and 98, respectively, which supply trickle currents I_{T3} and I_{T4}, respectively.

The cascode implementation with trickle currents shortens the delay time of the differential current switch 92 of the driver circuit 90, as described for the DAC cell 52 of FIG. 3. In addition, it helps to set the proper DC threshold level while maintaining a low overall output impedance, allowing for a reduction of the output voltage swing, which will reduce the voltage coupling into the DAC current steering switches, thereby improving the overall DAC's settling time.

A design example follows to illustrate the setting of the voltage range. In this example, the goal is to limit the voltage swing from −1.2 V to −1.6 V (a range of only 0.4 volts, half the range of the prior art circuit of FIG. 2), without increasing the output impedance. Assume the base of Q10 is more positive than Q11. The voltage drop across the collector resistor of Q14 is given by R_{S}(I_{S})+R_{S}(I_{T3}). Setting −Bₙ=−R_{S}(I_{S}+I_{T3})−V_{BEQ12} (where V_{BEQ12} is the base to emitter voltage of Q12, which is approximately 0.8 V) to −1.6 V, then (I_{S}+I_{T3})=(1.6−0.8)/R_{S}=0.8/R_{S}. Let R_{S}=1.6 kΩ. Then I_{S}+I_{T3}=0.5 mA. This sets the lower level of the voltage swing.

Now, let transistor Q10 turn off, and set −Bₙ=−R_{S}(I_{T3})0.8 V to −1.2 V. Solving for I_{T3}, I_{T3}=0.4 V/1.6 kΩ=0.25 mA. Thus, if I_{S} is set to 0.25 mA, and I_{T3} and I_{T4} are each equal to 0.25 mA, then the combined goals of reducing the voltage swing to the input of the DAC without increasing the output impedance of the drive circuitry are met.

Thus, the present invention has been described herein with reference to a particular embodiment for a particular application. Those having ordinary skill in the art and access to the present teachings will recognize additional modifications, applications and embodiments within the scope thereof.

It is therefore intended by the appended claims to cover any and all such applications, modifications and embodiments within the scope of the present invention.

Accordingly,

WHAT IS CLAIMED IS:

1. A current switch comprising:
a differential pair of transistors Q1 and Q2;
a pair of cascode transistors Q_{A} and Q_{B} coupled to Q1 and Q2, respectively; and
first means for maintaining said transistors Q_{A} and Q_{B} in an ‘on’ state regardless of the states of Q1 and Q2.

2. The invention of claim 1 wherein said first means includes a first current source adapted to supply a first trickle current to said transistor Q_{A}.

3. The invention of claim 2 wherein said first means further includes a second current source adapted to supply a second trickle current to said transistor Q_{B}.

4. The invention of claim 3 wherein said first and second current sources are coupled to the emitters of Q_{A} and Q_{B}, respectively.

5. The invention of claim 3 wherein said first and second trickle currents are approximately equal.

6. The invention of claim 1 wherein the emitters of Q_{A} and Q_{B} are coupled to the collectors of Q1 and Q2, respectively.

7. The invention of claim 1 wherein the collectors of Q_{A} and Q_{B} are coupled to first and second outputs, respectively.

8. The invention of claim 1 wherein the bases of Q_{A} and Q_{B} are connected in common to a voltage source V_{REF4}.

9. The invention of claim 8 wherein said voltage source V_{REF4} has low impedance.

10. The invention of claim 9 wherein said voltage source V_{REF4} includes a Schottky diode.

11. The invention of claim 10 wherein said voltage source V_{REF4} further includes a current source coupled to said Schottky diode.

12. The invention of claim 3 wherein said current switch further includes a third current source adapted to supply a third current to the common emitters of Q1 and Q2.

13. The invention of claim 12 wherein said first and second trickle currents are significantly smaller than said third current.

14. The invention of claim 12 wherein said current switch further includes second means for supplying complementary input signals Bₙ and −Bₙ.

15. The invention of claim 14 wherein said transistors Q1 and Q2 are adapted to couple said third current to either the collector of Q1 or the collector of Q2 in response to said complementary input signals Bₙ and −Bₙ.

16. The invention of claim 15 wherein the bases of Q1 and Q2 are coupled to said complementary input signals Bₙ and −Bₙ.

17. The invention of claim 12 wherein said current switch further includes a transistor Q5 connected between said third current source and the common emitters of Q1 and Q2.

18. The invention of claim 17 wherein the base of Q5 is coupled to a voltage supply V_{REF2}.

19. The invention of claim 14 wherein said second means includes a driver circuit.

20. The invention of claim 19 wherein said driver circuit includes a current switch comprising:
a fourth current source for supplying a fourth current;
a differential pair of transistors Q10 and Q11 adapted to couple said fourth current to either the collector of Q10 or the collector of Q11 in response to complementary input signals Xₙ and −Xₙ;
a pair of cascode transistors Q14 and Q15 having emitters coupled to the collectors of Q10 and Q11, respectively; and
fifth and sixth current sources adapted to supply trickle currents to the emitters of Q14 and Q15, respectively, in order to maintain said transistors Q14 and Q15 in an ‘on’ state regardless of the states of Q10 and Q11.

21. The invention of claim 20 wherein said driver circuit further includes two transistors Q12 and Q13 having bases coupled to the collectors of Q14 and Q15, respectively, collectors coupled to ground, and emitters coupled to outputs −Bₙ and Bₙ, respectively.

22. A current switch comprising:
a first current source for supplying a first current;
a differential pair of transistors Q1 and Q2 adapted to couple said first current to either the collector of Q1 or the collector of Q2 in response to complementary input signals Bₙ and −Bₙ;
a pair of cascode transistors Q_{A} and Q_{B} having emitters coupled to the collectors of Q1 and Q2, respectively; and
second and third current sources adapted to supply first and second trickle currents to the emitters of Q_{A} and Q_{B}, respectively, in order to maintain said transistors Q_{A} and Q_{B} in an ‘on’ state regardless of the states of Q1 and Q2.

23. A driver circuit comprising:
a first current source for supplying a first current;
a differential pair of transistors Q10 and Q11 adapted to couple said first current to either the collector of Q10 or the collector of Q11 in response to complementary input signals Xₙ and −Xₙ;
a pair of cascode transistors Q14 and Q15 having emitters coupled to the collectors of Q10 and Q11, respectively;
second and third current sources adapted to supply first and second trickle currents to the emitters of Q14 and Q15, respectively, in order to maintain said transistors Q14 and Q15 in an ‘on’ state regardless of the states of Q10 and Q11; and
two transistors Q12 and Q13 having bases coupled to the collectors of Q14 and Q15, respectively, and emitters adapted to output voltages −Bₙ and Bₙ, respectively.

24. The invention of claim 23 wherein the collectors of Q14 and Q15 are each connected to ground through a resistor R_{S}.

25. The invention of claim 23 wherein the collectors of Q12 and Q13 are connected to ground.

26. The invention of claim 23 wherein said driver circuit further includes fourth and fifth current sources coupled to the emitters of Q12 and Q13, respectively.

27. The invention of claim 23 wherein said first current and said first and second trickle currents are chosen to generate a desired output voltage swing at the emitters of Q12 and Q13.

28. A digital to analog converter comprising:
a first current summing bus;
a second current summing bus; and
a plurality of current switches, each switch including:
a first current source for supplying a first current;
a differential pair of transistors Q1 and Q2 adapted to couple said first current to either the first current summing bus or the second current summing bus in response to complementary input signals Bₙ and −Bₙ;
a pair of cascode transistors Q_{A} and Q_{B} having emitters coupled to the collectors of Q1 and Q2, respectively, and collectors coupled to said first and second current summing buses, respectively; and
second and third current sources adapted to supply first and second trickle currents to the emitters of Q_{A} and Q_{B}, respectively, in order to maintain said transistors Q_{A} and Q_{B} in an ‘on’ state regardless of the states of Q1 and Q2.

29. The invention of claim 28 wherein the bases of Q_{A} and Q_{B} are connected in common to a voltage source V_{REF4}.

30. The invention of claim 29 wherein said voltage source V_{REF4} has low impedance.

31. The invention of claim 29 wherein said voltage source V_{REF4} includes a Schottky diode.

32. The invention of claim 31 wherein said voltage source V_{REF4} further includes a current source coupled to said Schottky diode.

33. The invention of claim 28 wherein each current switch further includes a transistor Q5 connected between said first current source and the common emitters of Q1 and Q2.

34. The invention of claim 33 wherein the base of Q5 is coupled to a voltage Supply V_{REF2}.

35. The invention of claim 28 wherein said first and second trickle currents are approximately equal.

36. The invention of claim 28 wherein said first and second trickle currents are significantly smaller than said first current.

37. The invention of claim 28 wherein each current switch further includes a driver circuit for supplying said complementary input signals Bₙ and −Bₙ.

38. The invention of claim 37 wherein said driver circuit includes:
a fourth current source for supplying a fourth current;
a differential pair of transistors Q10 and Q11 adapted to couple said fourth current to either the collector of Q10 or the collector of Q11 in response to complementary input signals Xₙ and −Xₙ;
a pair of cascode transistors Q14 and Q15 having emitters coupled to the collectors of Q10 and Q11, respectively;
fifth and sixth current sources adapted to supply third and fourth trickle currents to the emitters of Q14 and Q15, respectively, in order to maintain said transistors Q14 and Q15 in an ‘on’ state regardless of the states of Q10 and Q11; and
two transistors Q12 and Q13 having bases coupled to the collectors of Q14 and Q15, respectively, and emitters adapted to output voltages −Bₙ and Bₙ, respectively.

39. The invention of claim 38 wherein said fourth current and said third and fourth trickle currents are chosen to generate a low output voltage swing at the emitters of Q12 and Q13.

40. A method for increasing the speed of a current switch comprising a differential pair of transistors Q1 and Q2 including the steps of:
connecting a pair of cascode transistors Q_{A} and Q_{B} to the outputs of Q1 and Q2, respectively, and
supplying trickle currents to said transistors Q_{A} and Q_{B} in order to keep them in an ‘on’ state regardless of the states of Q1 and Q2.
